(19) United States
(12) Patent Application Publication
(10) Pub. No.: US 2025/0157874 A1
(43) Pub. Date: May 15, 2025

(54) SEMICONDUCTOR PACKAGE

(71) Applicant: SAMSUNG ELECTRONICS CO., LTD., Suwon-si (KR)

(72) Inventor: Junghoon KANG, Suwon-si (KR)

(73) Assignee: SAMSUNG ELECTRONICS CO., LTD., Suwon-si (KR)

(21) Appl. No.: 18/740,039

(22) Filed: Jun. 11, 2024

(30) Foreign Application Priority Data
Nov. 14, 2023 (KR) 10-2023-0157112

(51) Int. Cl. H01L 23/367; H01L 23/00; H01L 23/31; H01L 23/498; H01L 25/065

(52) U.S. Cl. CPC H01L 23/3675; H01L 23/3128; H01L 23/49816; H01L 23/49822; H01L 24/05; H01L 24/13; H01L 25/0652; H01L 2224/05009; H01L 2224/05025; H01L 2224/13007; H01L 2224/13024; H01L 2924/01029; H01L 2924/1431; H01L 2924/1434; H01L 2924/15311

(57) ABSTRACT

A semiconductor package includes a frame on a redistribution substrate, the frame including an interconnection structure and having a cavity, a first semiconductor chip on the redistribution substrate in the cavity, the first semiconductor chip having a heat dissipation layer on an upper surface thereof, an encapsulation layer having a first portion on the first semiconductor chip, and a second portion on the upper surface of the frame, heat dissipation pads on the first portion, and respectively having a heat dissipation via connected to the heat dissipation layer passing through the encapsulation layer, and including a mark pad having a mark, connection pads on the second portion, and respectively having a connection via connected to the interconnection structure through the encapsulation layer, a second semiconductor chip on the encapsulation layer, and connected to the connection pads, and a heat sink on the heat dissipation pads.

### CROSS-REFERENCE TO RELATED APPLICATION(S)

This application claims priority to Korean Patent Application No. 10-2023-0157112, filed on Nov. 14, 2023, in the Korean Intellectual Property Office, the disclosure of which is incorporated by reference herein in its entirety.

### BACKGROUND

The present disclosure relates to a semiconductor package.

Recently, in the electronic products market, demand for portable devices has been rapidly increasing, and accordingly, miniaturization and weight reductions of electronic components mounted on products, such as portable devices, have been advantageous. In order to reduce the size and weight of electronic components, it is also advantageous to improve a degree of integration of semiconductor devices used for electronic components. In particular, semiconductor packages having a structure which effectively dissipates heat generated by a semiconductor chip may be advantageous.

### SUMMARY

One or more example embodiments provide a semiconductor package that may have improved heat dissipation performance and improved mark visibility.

According to an aspect of an example embodiment, a semiconductor package includes: a redistribution substrate including a redistribution layer; a frame on the redistribution substrate and defining a cavity, wherein the frame includes an interconnection structure connected to the redistribution layer and extending to an upper surface of the frame; a first semiconductor chip on the redistribution substrate and in the cavity, the first semiconductor chip being connected to the redistribution layer, wherein the first semiconductor chip includes a heat dissipation layer on an upper surface of the first semiconductor chip; an encapsulation layer including a first portion on the first semiconductor chip in the cavity, and a second portion on the upper surface of the frame; heat dissipation pads on the first portion of the encapsulation layer, each of the heat dissipation pads including a heat dissipation via passing through the encapsulation layer, the heat dissipation via being connected to the heat dissipation layer, wherein the heat dissipation pads include a mark pad including an engraved mark; connection pads on the second portion of the encapsulation layer, each of the connection pads including a connection via passing through the encapsulation layer, the connection via being connected to the interconnection structure; a second semiconductor chip on the encapsulation layer and connected to the connection pads; and a heat sink on the heat dissipation pads.

According to an aspect of an example embodiment, a semiconductor package includes: a redistribution substrate including a redistribution layer; a frame on the redistribution substrate and defining a cavity, wherein the frame includes an interconnection structure connected to the redistribution layer and to an upper surface of the frame; a first semiconductor chip on the redistribution substrate and in the cavity, the first semiconductor chip including first chip pads connected to the redistribution layer, wherein the first semiconductor chip includes a heat dissipation layer on an upper surface of the first semiconductor chip; an encapsulation layer on the upper surface of the frame and filling the cavity, the encapsulation layer having a plurality of openings, which open pad regions of the interconnection structure; heat dissipation pads on the encapsulation layer, each of the heat dissipation pads including a heat dissipation via passing through the encapsulation layer, the heat dissipation via being connected to the heat dissipation layer, wherein the heat dissipation pads include a mark pad including an engraved mark; a second semiconductor chip including second chip pads connected to the pad regions by conductive bumps; and a heat sink on the heat dissipation pads.

According to an aspect of an example embodiment, a semiconductor package including: a redistribution substrate including a redistribution layer; a frame on the redistribution substrate and defining a cavity, wherein the frame includes an interconnection structure connected to the redistribution layer and extending to an upper surface of the frame; a first semiconductor chip on the redistribution substrate and in the cavity, the first semiconductor chip including first chip pads connected to the redistribution layer, wherein the first semiconductor chip includes a heat dissipation layer on an upper surface of the first semiconductor chip; an encapsulation layer including a first portion encapsulating the first semiconductor chip in the cavity, and a second portion on the upper surface of the frame; heat dissipation pads on the first portion of the encapsulation layer, each of the heat dissipation pads including a heat dissipation via passing through the encapsulation layer, the heat dissipation via being connected to the heat dissipation layer; connection pads on the second portion of the encapsulation layer, each of the connection pads including a connection via passing through the encapsulation layer, the connection via being connected to the interconnection structure; a second semiconductor chip on the encapsulation layer, the second semiconductor chip including second chip pads respectively connected to the connection pads by a conductive bump; a heat sink on the heat dissipation pads; and a thermally conductive bonding layer between the heat sink and the heat dissipation pads, wherein the thermally conductive bonding layer thermally couples the heat sink to the heat dissipation pads.

### BRIEF DESCRIPTION OF THE DRAWINGS

The above and other aspects, features, and advantages will become more apparent from the following detailed description, taken in conjunction with the accompanying drawings, in which:

FIG. 1 is a side cross-sectional view of a semiconductor package according to one or more example embodiments;

FIG. 2 is an upper plan view of the semiconductor package of FIG. 1, according to one or more example embodiments;

FIGS. 3A and 3B are plan views of the semiconductor package of FIG. 1, taken along lines I-I′ and II-II′, according to one or more example embodiments;

FIG. 4 is a plan view of a semiconductor package according to one or more example embodiments;

FIG. 5 is a side cross-sectional view of a semiconductor package according to one or more example embodiments;

FIGS. 6A, 6B, 6C and 6D are cross-sectional views of some processes of a method of manufacturing a semiconductor package according to one or more example embodiments; and

FIGS. 7A, 7B, 7C, 7D and 7E are cross-sectional views of other processes of a method of manufacturing a semiconductor package according to one or more example embodiments.

### DETAILED DESCRIPTION

Hereinafter, various example embodiments will be described in detail with reference to the accompanying drawings. The same reference numerals are used for the same components in the drawings, and duplicate descriptions thereof are omitted.

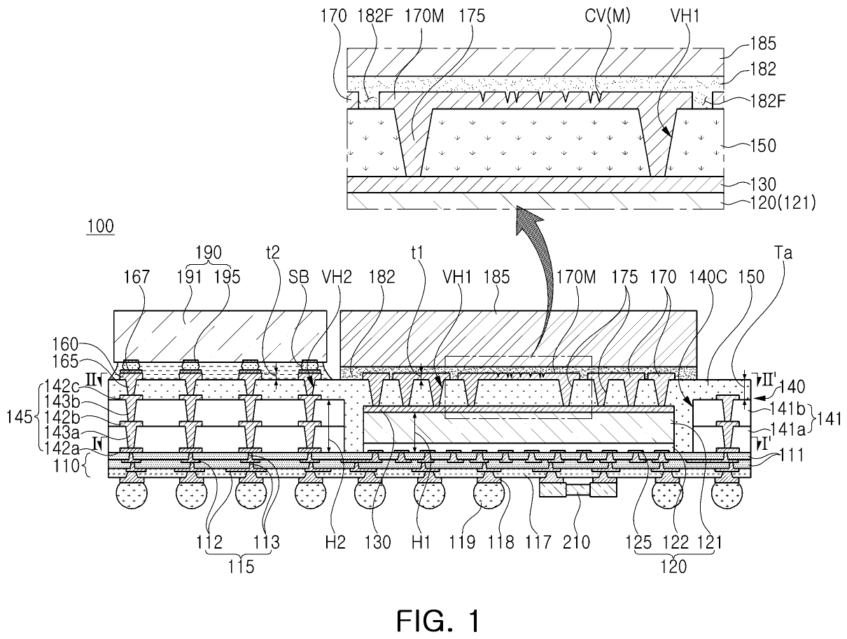

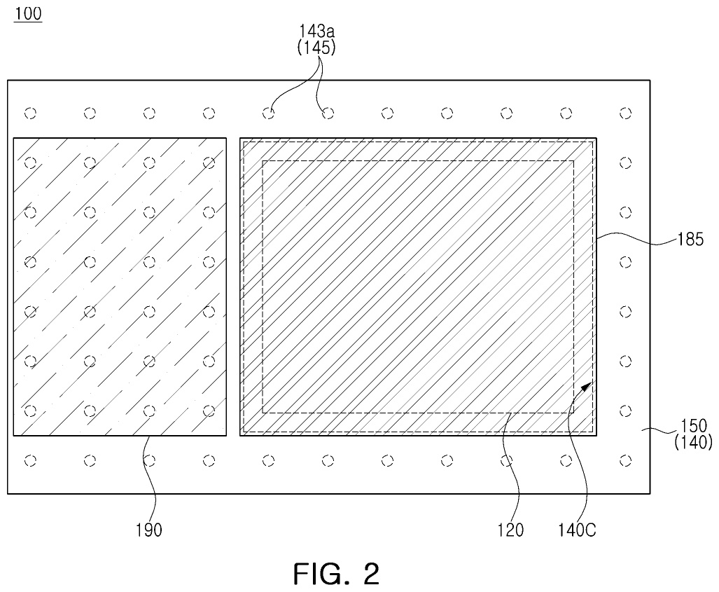

FIG. 1 is a side cross-sectional view of a semiconductor package according to one or more example embodiments. FIG. 2 is an upper plan view of the semiconductor package of FIG. 1, according to one or more example embodiments.

Referring to FIGS. 1 and 2, a semiconductor package 100 according to one or more example embodiments may include a redistribution substrate 110 having a redistribution layer 115, a frame 140 having a cavity 140c on the redistribution substrate 110, a first semiconductor chip 120 disposed in the cavity 140c, an encapsulation layer 150 disposed in the cavity 140c and on an upper surface of the frame 140, a heat sink 185 disposed on the encapsulation layer 150, and a second semiconductor chip 190 disposed on the encapsulation layer 150. According to one or more example embodiments, the encapsulation layer 150 may be divided into a first portion, covering the first semiconductor chip 120 in the cavity 140c, and a second portion, covering the upper surface of the frame 140.

The semiconductor package 100 according to one or more example embodiments may include heat dissipation pads 170, disposed on the first portion of the encapsulation layer 150, and connection pads 160, disposed on the second portion of the encapsulation layer 150. Each of the heat dissipation pads 170 may have a heat dissipation via 175 passing through the first portion of the encapsulation layer 150, and each of the connection pads 160 may have a connection via 165 passing through the second portion of the encapsulation layer 150.

In one or more example embodiments, the heat dissipation pads 170 may provide a path to release heat generated by the first semiconductor chip 120 to the heat sink 185. In addition, the heat dissipation pads 170 may include a mark pad 170M having a mark M engraved therein. A more detailed description thereof will be described below according to one or more example embodiments.

The redistribution substrate 110 may include a plurality of insulating layers 111 and a redistribution layer 115 formed on each of the plurality of insulating layers 111. It is illustrated that the redistribution substrate 110 according to one or more example embodiments includes a two-layer insulating layer 111 and a two-layer redistribution layer 115, but in one or more example embodiments, the redistribution substrate 110 may include insulating layers and redistribution layers comprising more than one or two insulating layers and redistribution layers. For example, according to one or more example embodiments, the insulating layer 111 may be formed of a photosensitive insulating material such as a photosensitive insulating (PID) resin. When the insulating layer 111 is a photosensitive insulating resin, the redistribution layer 115 may be formed to have a fine pattern using a photolithography process. In one or more example embodiments, the insulating layer 111 may include a thermosetting resin such as an epoxy resin, or a thermoplastic resin such as polyimide.

The redistribution layer 115 may include a redistribution pattern 112, disposed on the insulating layer 111, and a redistribution via 113 connected to the redistribution pattern 112, the redistribution via 113 passing through the insulating layer 111. On the same level (for example, the same insulating layer), the redistribution via 113 may be formed together with the redistribution pattern 112, using the same plating process. For example, the redistribution layer 115 may include a conductive material such as copper (Cu), aluminum (Al), silver (AG), tin (Sn), gold (AU), nickel (Ni), lead (Pb), titanium (Ti), or alloys thereof. In one or more example embodiments, the redistribution layer 115 may include an additional pattern (for example, a ground pattern) having various functions. The redistribution via 113 may have a tapered structure determined by a direction in which redistribution via 113 is formed. In one or more example embodiments, the redistribution via 113 may have a width decreasing from a lower surface of the redistribution substrate 110 toward an upper surface of the redistribution substrate 110.

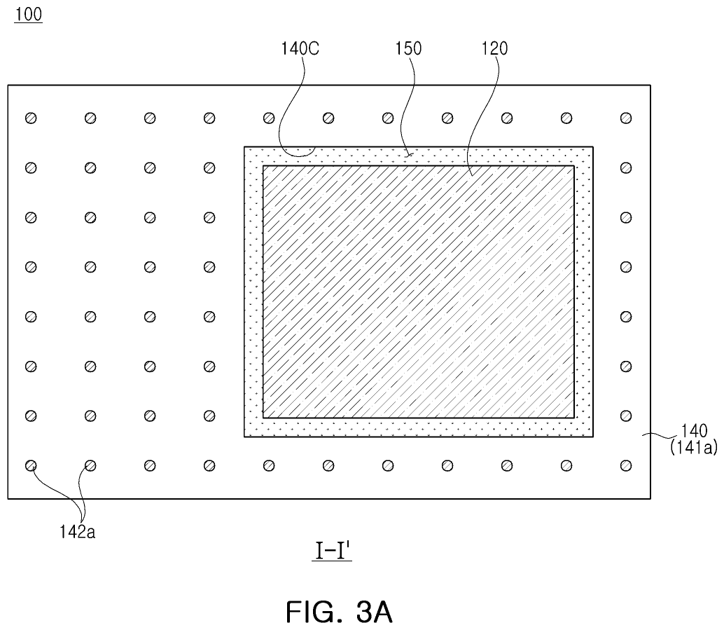

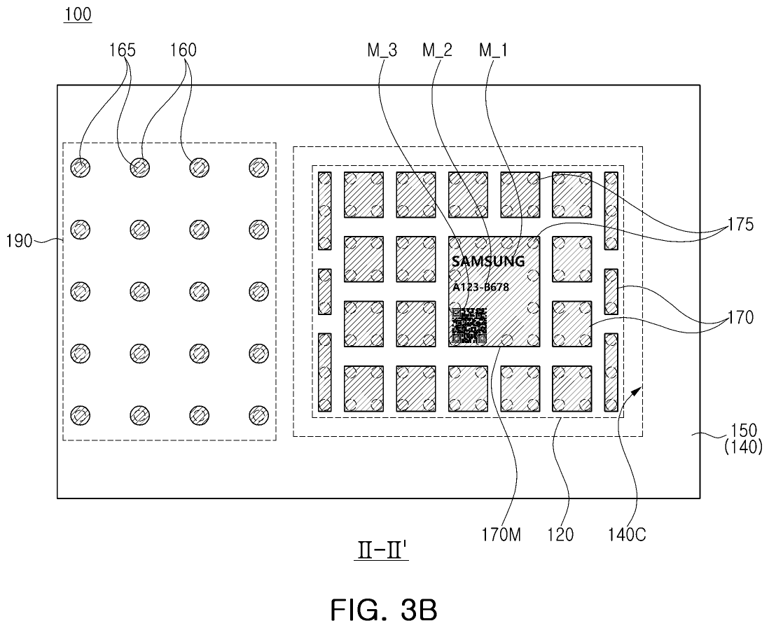

The frame 140 may be disposed on the redistribution substrate 110, and may include an interconnection structure 145 connected to the redistribution layer 115, the interconnection structure 145 extending onto the upper surface of the frame 140. The frame 140 may be electrically connected to the first semiconductor chip 120 through the redistribution layer 115. FIG. 3B is a plan view of the semiconductor package of FIG. 1, taken along line I-I′, according to one or more example embodiments. In a plan view, an interconnection structure 145 may be arranged across the frame 140. In one or more example embodiments, the interconnection structure 145 may be disposed to surround the cavity 140c in the frame 140.

In one or more example embodiments, the frame 140 may include a first insulating layer 141a, a first interconnection layer 142a connected to the redistribution layer 115 and embedded in the first insulating layer 141a, a second interconnection layer 142b disposed on a side, opposite to a side of the first insulating layer 141a in which the first interconnection layer 142a is embedded, a second insulating layer 141b disposed on the first insulating layer 141a, the second insulating layer 141b covering the second interconnection layer 142b, and a third interconnection layer 142c disposed on the second insulating layer 141b. The first, second and third interconnection layers 142a, 142b, and 142c may be electrically connected to each other through first and second interconnection vias 143a and 143b respectively passing through the first and second insulating layers 141a and 141b. The frame 140 may be manufactured to have a sufficient thickness using a substrate process. Conversely, the redistribution substrate 110 may be manufactured to have a small thickness using a semiconductor process or the like. Thus, a thickness of each of the first, second and third interconnection layers 142a, 142b, and 142c of the frame 140 may be greater than a thickness of the redistribution pattern 112 of the redistribution substrate 110. For example, at least one of the first and second insulating layers 141a and 141b may include a thermosetting resin such as an epoxy resin, a thermoplastic resin such as polyimide, and a resin mixed with an inorganic filler or impregnated with a glass fiber (e.g., glass cloth or glass fabric) together with an inorganic filler. In a specific example, at least one of the first and second insulating layers 141a and 141b may include a prepreg, an Ajinomoto build-up film (ABF), FR-4, BT, or the like. For example, the first, second and third interconnection layers 142a, 142b, and 142c may include a conductive material such as copper (Cu), aluminum (Al), silver (Ag), tin (Sn), gold (Au), nickel (Ni), lead (Pb), titanium (Ti), or alloys thereof. The first, second and third interconnection layers 142a, 142b, and 142c may perform various functions depending on a design of a corresponding layer. First and second interconnection vias 143a and 143b may be integrated with the second and third interconnection layers 142b and 142c, respectively.

The frame 140 according to one or more example embodiments may have a cavity 140C adjacent to one side thereof and deviating from the center thereof. The first semiconductor chip 120 may be disposed on the redistribution substrate 110 in the cavity 140C, and may be electrically connected to the redistribution layer 115. In one or more example embodiments, a first chip pad 125 of the first semiconductor chip 120 may be connected to the redistribution layer 115 through the redistribution via 113. The first semiconductor chip 120 may include a first semiconductor substrate 121 having a lower surface (that is, an active surface) on which a circuit layer 122 is formed, and an upper surface (that is, an inactive surface), and first chip pads 125 may be arranged on the circuit layer 122. For example, the first semiconductor substrate 121 may include silicon (Si), germanium (Ge), and gallium arsenide (GaAs). As used herein, the “active surface” may have an active region doped with impurities, and various devices (for example, transistors) may be formed in the active region. The circuit layer 122 may include an interconnection circuit connected to the devices. A mounting height H1 of the first semiconductor chip 120 may be similar to an upper-surface level H2 of the frame 140. When the third interconnection layer 142c of the interconnection structure 145 protrudes from the upper surface of the frame 140, the upper-surface level H2 of the frame 140 may be defined as an upper-surface level of the third interconnection layer 142c. In one or more example embodiments, the mounting height H1 of the first semiconductor chip 120 may be lower than or the equal to the upper-surface level H2 of the frame 140.

The first semiconductor chip 120 may be a chip serving as a large heat source, such as a processor chip or a controller chip. For example, the first semiconductor chip 120 may be a microprocessor, a graphics processor, a signal processor, a network processor, a chipset, an audio codec, a video codec, an application processor, a system on chip (SoC), an application-specific integrated circuit (ASIC), or a power management integrated circuit (PMIC), but one or more example embodiments are not limited thereto. In one or more example embodiments, the first semiconductor chip 120 may be a SoC.

The first semiconductor chip 120 according to one or more example embodiments may have a heat dissipation layer 130 disposed on an upper surface thereof. The heat dissipation layer 130 may include one or more metal layers having excellent thermal conductivity. For example, the heat dissipation layer 130 may include Cu or Ti/Cu. The heat dissipation layer 130 may be formed by being deposited on an inactive surface of a wafer at a wafer level of the first semiconductor chip 120. In this case, the heat dissipation layer 130 may have an area corresponding to that of the upper surface of the first semiconductor chip 120. The heat dissipation layer 130 may be provided as a primary heat dissipation path directly disposed on the first semiconductor chip 120.

As described above, the encapsulation layer 150 may have a first portion filled in the cavity 140C, the first portion covering the semiconductor chip 120, and a second portion covering the upper surface of the frame 130. The encapsulation layer 150 may include, for example, a thermosetting resin such as an epoxy resin or a thermoplastic resin such as polyimide. In one or more example embodiments, a molding portion may be formed of an ABF or epoxy molding compound (EMC).

As described above, the heat dissipation pads 170 may be disposed on the first portion of the encapsulation layer 150, and the heat dissipation pads 170 may have a heat dissipation via 175 connected to the heat dissipation layer 130. Similarly, the connection pads 160 may be disposed on the second portion of the encapsulation layer 150, and the connection pads 160 may have a connection via 165 connected to the interconnection structure 145 (in particular, the third interconnection layer 142c). The heat dissipation via 175 may be formed in a first hole VH1 passing through the first portion of the encapsulation layer 150 and opening a portion of the heat dissipation layer 130, and the connection via 165 may be formed in a second hole VH2 passing through the second portion of the encapsulation layer 150 and opening a portion of the third interconnection layer 142c. In addition, the heat dissipation pads 170 may have a structure integrated with the heat dissipation via 175, and similarly, the connection pads 160 may have a structure integrated with the connection via 165.

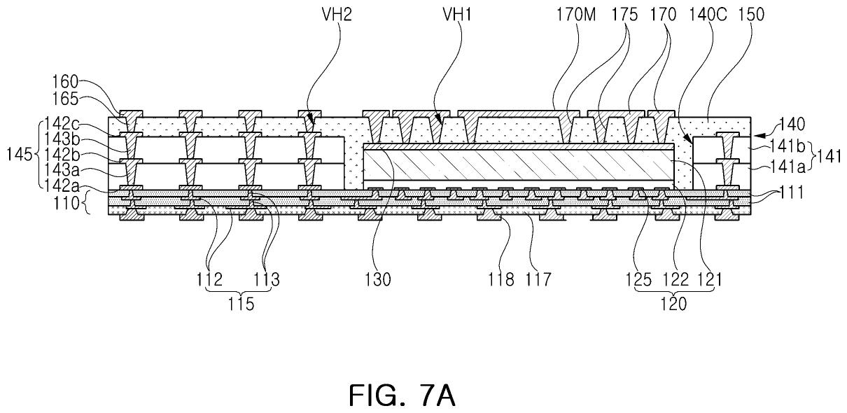

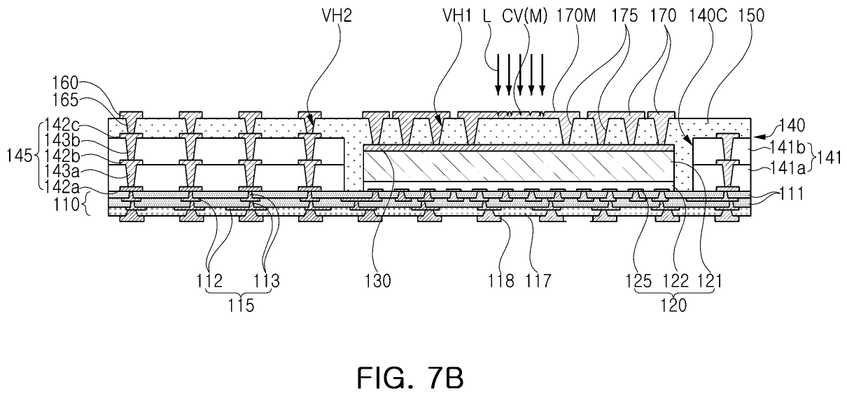

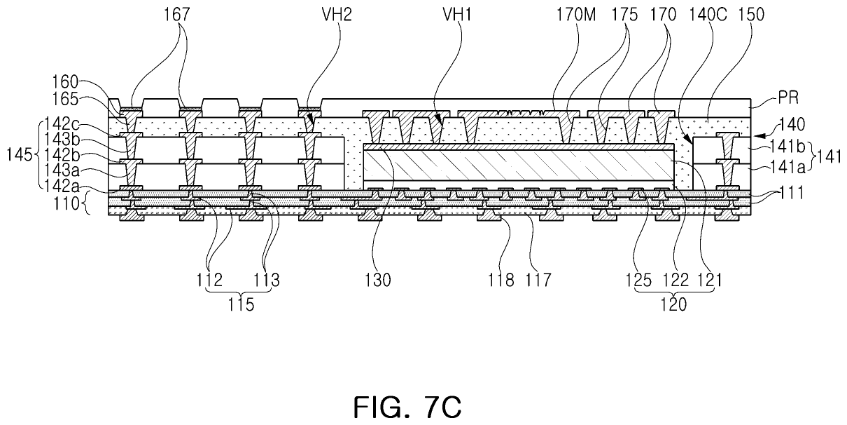

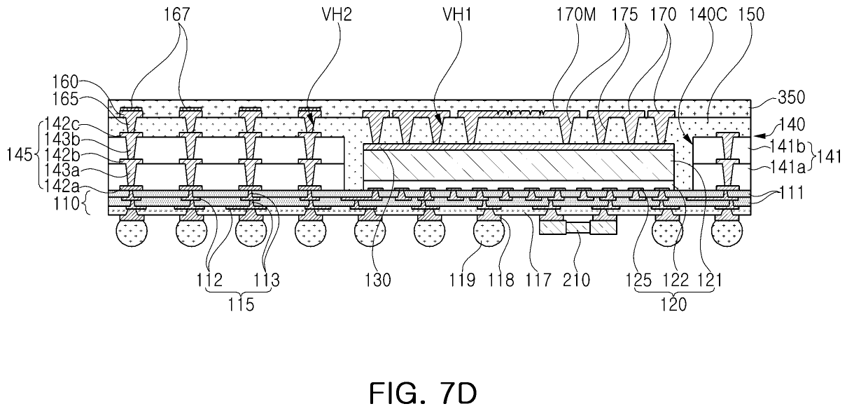

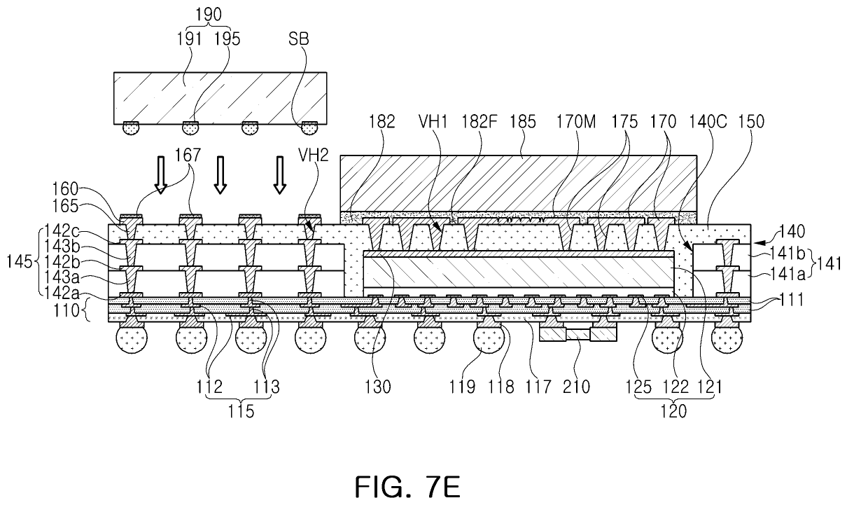

In the same process, the heat dissipation pads 170 may be formed together with the connection pads 160 (see FIG. 7A). The heat dissipation pads 170 may include a material the same as that of the connection pads 160. For example, the heat dissipation pads 170 and the connection pads 160 may include copper (Cu). In one or more example embodiments, on the encapsulation layer 150, a thickness t1 of each of the heat dissipation pads 170 may be substantially equal to a thickness t2 of each of the connection pads 160. A height difference between the heat dissipation via 175 and the connection via 165 may be determined by an upper-surface level difference (H2-H1) between the first semiconductor chip 120 and the frame 140.

In one or more example embodiments, the heat dissipation pads 170 may be connected to the heat dissipation layer 130 of the first semiconductor chip 120 through the heat dissipation via 175. FIG. 3B is a plan view of the semiconductor package of FIG. 1, taken along line II-II′.

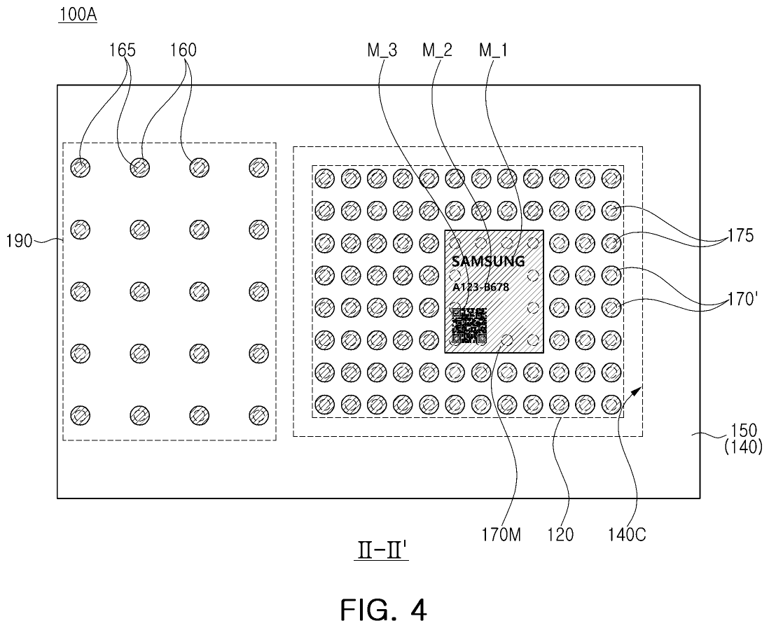

As illustrated in FIG. 3B, heat dissipation vias 175 may be arranged across the upper surface of the first semiconductor chip 120, and may connect the heat dissipation layer 130 and the heat dissipation pad 170 to each other to provide a heat dissipation path passing through the encapsulation layer 150 having relatively low thermal conductivity. The heat dissipation pads 170 may also be arranged over the entire heat dissipation area (for example, the upper surface of the first semiconductor chip 120). In one or more example embodiments, the heat dissipation pad 170 may have a planar shape different from that of the connection pad 160. The heat dissipation pad 170 may have an area larger than the area of the connection pad 160 in consideration of heat dissipation performance. For example, the heat dissipation pad 170 is illustrated as having a rectangular pattern, but may have various shapes and arrangements according to one or more example embodiments. Alternatively, as illustrated in FIG. 4, a semiconductor package 100A according to one or more example embodiments may include a heat dissipation pad 170′ having a planar shape similar to that of the connection pad 160. For example, the heat dissipation pad 170′ and the connection pad 160 may have a circular shape, and each of the heat dissipation pad 170′ and the connection pad 160 may be connected to one heat dissipation via 175′.

In one or more example embodiments, the heat sink 185 may be coupled to the heat dissipation pads 170 by a thermally conductive bonding layer 182. The thermally conductive bonding layer 182 may be filled in a space between the heat dissipation pads 170 to ensure high bonding strength. A portion of the thermally conductive bonding layer 182 filled in the space between the heat dissipation pads 170 may be bonded to the encapsulation layer 150. For example, the thermally conductive bonding layer 182 may include a thermal interface material (TIM) such as thermal grease.

In one or more example embodiments, heat emitted from the first semiconductor chip 120 may be transmitted to the heat sink 185 disposed on the heat dissipation pads 170 through a new heat dissipation path including the heat dissipation layer 130, the heat dissipation via 175, and the heat dissipation pad 170, and the heat may be externally discharged.

The semiconductor package 100 according to one or more example embodiments not only may provide a new heat dissipation path, but also may have an identification mark M having excellent visibility using some heat dissipation pads, among the heat dissipation pads 170.

In one or more example embodiments, one of the heat dissipation pads 170 may include a mark pad 170M having a mark M engraved therein (i.e., an engraved pattern CV). The mark pad 170M may have an area larger than those of other heat dissipation pads 170. In a similar manner to the other heat dissipation pads 170, the mark pad 170M may also be connected to the heat dissipation layer 130 through the heat dissipation via 175, and may also be used as a heat dissipation element. For example, in the same manner as the heat dissipation pad 170, the mark pad 170M may be provided as a metal pad such as copper (Cu).

In one or more example embodiments, the mark M of the mark pad 170M may have an engraved pattern CV by performing engraving using a laser. For example, a depth at which engraving is performed to create the mark M may be less than a thickness of the mark pad 170M. The marks M may be formed on the mark pad 170M, a metal, thereby improving visibility further than that of a mark M formed on a resin such as the encapsulation layer 150. For example, a mark M formed on the encapsulation layer 150, an ABF, by performing engraving may have a gray value (GV) less than 20. In comparison, a mark M formed on the mark pad 170M, copper, may have a GV of about 70, which may greatly improve visibility.

The mark M formed on the mark pad 170M may include letters, numbers, recognition codes, and the like, representing various pieces of product information. For example, as illustrated in FIG. 3B, the mark M may include a logo mark M_1 including a logo of a manufacturing company or a sales company, a product number mark M_2, a 2D bar code, and various recognition codes M_3 such as a QR code. In addition, the thermally conductive bonding layer 182 may be filled in the mark M, the engraved pattern CV of the mark pad 170M.

The second semiconductor chip 190 may be disposed on the encapsulation layer 150 to be parallel to the heat sink 185. The second semiconductor chip 190 may include a semiconductor substrate 191 on which second chip pads 195 are arranged. The second chip pads 195 of the second semiconductor chip 190 may be connected to the connection pads 160. The second chip pads 195 may be respectively connected to the connection pads 160 by a conductive bump SB such as a solder ball. In one or more example embodiments, a bonding metal layer 167 may be disposed on the connection pads 160. For example, the bonding metal layer 167 may include a hot air solder leveling (HASL) layer or a Ni/Au plating layer. The semiconductor package 100 according to one or more example embodiments may further include an underfill filled in a space between the second semiconductor chip 190 and the encapsulation layer 150, the underfill surrounding the conductive bump SB.

The second semiconductor chips 190 each may be a volatile memory chip and/or a non-volatile memory chip. The volatile memory chip may include, for example, a dynamic random access memory (DRAM), a static RAM (SRAM), a thyristor RAM (TRAM), a zero capacitor RAM (ZRAM), or a twin transistor RAM (TTRAM). In addition, the non-volatile memory chip may include, for example, a flash memory, a magnetic RAM (MRAM), a spin-transfer torque MRAM (STT-MRAM), a ferroelectric RAM (FRAM), a phase change RAM (PRAM), a resistive RAM (RRAM), a nanotube RRAM, a polymer RAM, a nano floating gate memory, a holographic memory, a molecular electronics memory, or an insulator resistance change memory.

The semiconductor package 100 according to one or more example embodiments may further include a passivation layer 117 disposed on a lower surface of a first redistribution substrate 110, an underbump metallogy (UBM) layer 118 passing through the passivation layer 117, the UBM layer 118 being connected to the redistribution layer 115, and an electrical connection metal 119 disposed on the UBM layer 118. The first redistribution substrate 110 may be physically and/or electrically connected to an external device (for example, a main board) through the UBM layer 118 and the electrical connection metal 119. The electrical connection metal 119 may include solder such as a low melting point metal, for example, tin (Sn)-aluminum (Al)-copper (Cu). In one or more example embodiments, a conductive pillar may be included instead of the UBM layer 118. The semiconductor package 100 according to one or more example embodiments may further include a passive component 210 disposed on a lower surface of the redistribution substrate 110 and connected to the redistribution layer 115 through the UBM layer 118.

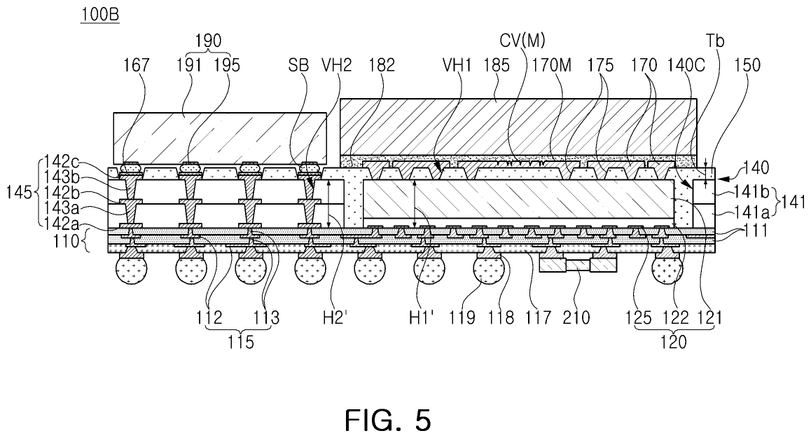

FIG. 5 is a side cross-sectional view of a semiconductor package according to one or more example embodiments.

Referring to FIG. 5, a semiconductor package 100B according to one or more example embodiments may be understood as being similar to the semiconductor package 100 illustrated in FIGS. 1, 2, 3A and 3B, except that a second semiconductor chip 190 is electrically connected to an interconnection structure 145 without connection pads (“160” in FIG. 1), a height of the semiconductor package 100B is reduced through such a connection structure, and the interconnection structure 145 in a frame 140 has a different arrangement. Unless otherwise stated, a description of components according to one or more example embodiments may refer to a description of the same or similar components of the semiconductor package 100 illustrated in FIGS. 1, 2, 3A and 3B.

In a similar manner to the above-described one or more example embodiments, an encapsulation layer 150 according to one or more example embodiments may have a first portion, filling a cavity 140C and covering a first semiconductor chip 120, and a second portion, covering an upper surface of the frame 140. In a similar manner to the above-described one or more example embodiments, heat dissipation pads 170 may be disposed on the first portion of the encapsulation layer 150, and the heat dissipation pads 170 may have a heat dissipation via 175 formed in a first hole VH1, passing through the first portion of the encapsulation layer 150. The heat dissipation via 175 may connect the heat dissipation pad 170 to a heat dissipation layer 130 on the first semiconductor chip 120. A second hole VH2, passing through the second portion of the encapsulation layer 150, may open a pad region of a third interconnection layer 142c of an interconnection structure 145. Unlike the above-described one or more example embodiments, a connection pad may not be formed in the second hole VH2, and a bonding metal layer 167 may be formed in the opened pad region. In the second hole VH2 (also referred to as an “opening”), the bonding metal layer 167 may be connected to second chip pads 195 of the second semiconductor chip 190 by a conductive bump SB.

As such, the second portion of the encapsulation layer 150 may not need to be formed to have a sufficient thickness Tb for forming a connection pad, and thus may be formed to have a thickness less than a thickness Ta of the second portion of the encapsulation layer 150 illustrated in FIG. 1. As a result, an overall thickness of the semiconductor package 100B may be reduced further than an overall thickness of the semiconductor package 100 in FIG. 1. A mounting height H1′ of a second semiconductor chip 120 according to one or more example embodiments may be lower than an upper-surface level H2′ of the frame 140.

In addition, the interconnection structure 145 in the frame 140 may have an arrangement different from that of the above-described one or more example embodiments. For example, the interconnection structure may be partially omitted in some regions of the frame 140 adjacent to the cavity 140C.

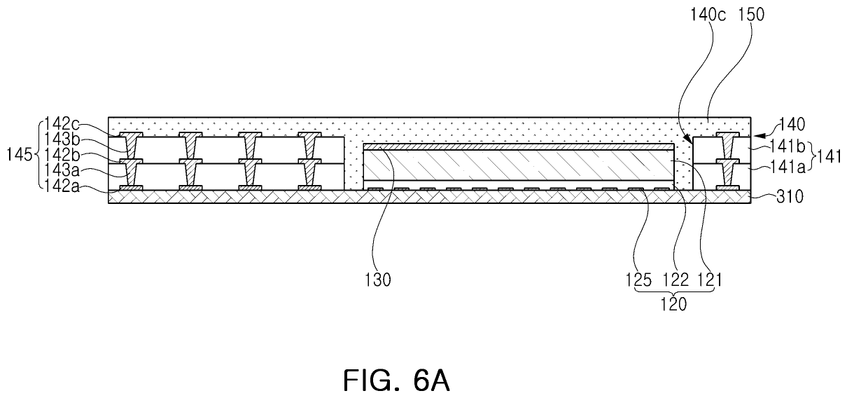

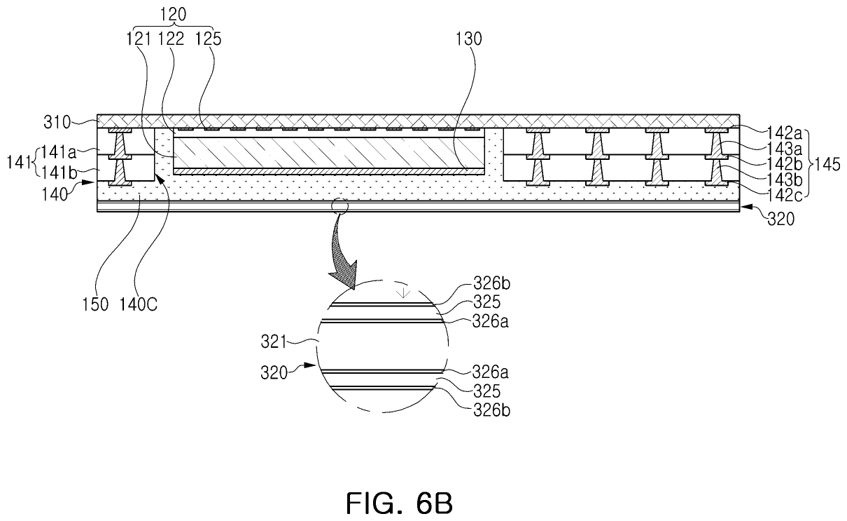

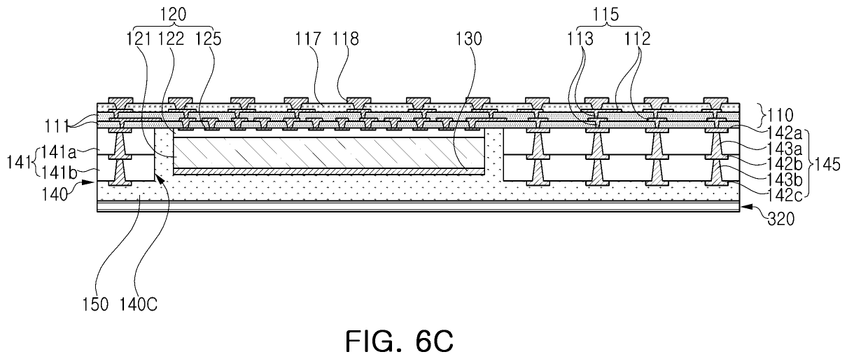

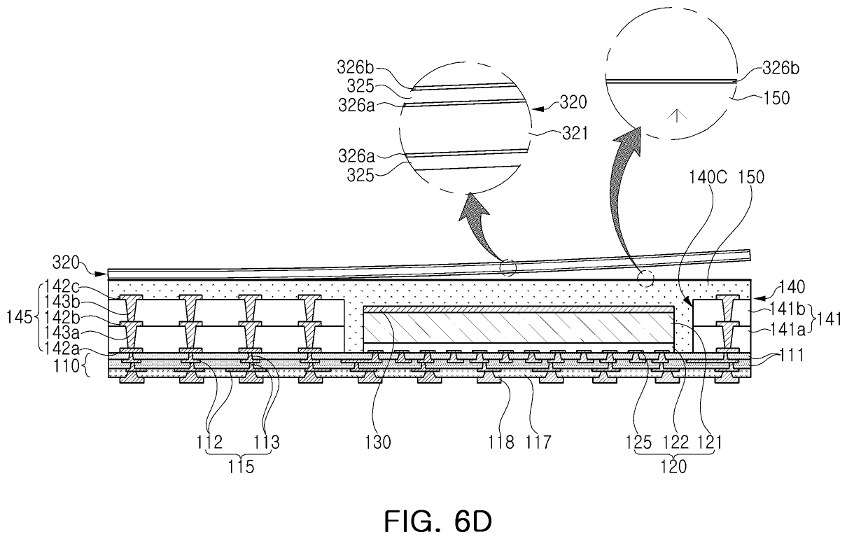

FIGS. 6A, 6B, 6C and 6D are cross-sectional views of some processes of a method of manufacturing a semiconductor package according to one or more example embodiments. The example processes represent a process of manufacturing a lower structure as part of a process of manufacturing the semiconductor package 100 illustrated in FIG. 1.

Referring to FIG. 6A, a frame 140 having a cavity 140C may be disposed on a die attach film 310, and a first semiconductor chip 120 may be accommodated in the cavity 140C. Thereafter, an encapsulation layer 150 may be formed.

The frame 140 according to one or more example embodiments may include an interconnection structure 145, together with first and second insulating layers 141a and 141b, as in the above-described one or more example embodiments (see FIG. 1), and the interconnection structure 145 may include first, second and third interconnection layers 142a, 142b, and 142c and interconnection vias 143a and 143b connecting the first, second and third interconnection layers 142a, 142b, and 142c to each other. The die attach film 310 may be attached to a lower side of the first insulating layer 141a. For example, the die attach film 310 may be an adhesive tape including an epoxy resin.

The frame 140 may have a cavity 140C asymmetrically disposed to be adjacent to one side thereof, and the first semiconductor chip 120 may be disposed in the cavity 140C. Subsequently, the cavity 140C may be filled to form an encapsulation layer 150, covering the first semiconductor chip 120 and an upper surface of the frame 140. The encapsulation layer 150 may be divided into a first portion, covering the first semiconductor chip 120 in the cavity 140C, and a second portion, covering the upper surface of the frame 140.

Referring to FIG. 6B, a carrier layer 320 may be attached to the encapsulation layer 150.

The carrier layer 320 according to one or more example embodiments may be a copper foil film. The carrier layer 320 may include various types of copper clad laminates. A copper clad laminate according to one or more example embodiments may be a double-sided copper clad laminate having a core resin layer 321 and a copper member disposed on both surfaces of the core resin layer 321. The copper member may include a first copper foil 326a in contact with the core resin layer 321, a second copper foil 326b providing an external surface, and a release layer 325 between the first and second copper foils 326a and 326b. In the present example process, the second copper foil 326b on one side of the carrier layer 320 may be bonded to the frame 140.

Referring to FIG. 6C, after the die attach film 310 is removed, a redistribution substrate 110 may be formed on the removed surface.

A process of forming the redistribution substrate 110 may form a multilayer redistribution circuit by repeatedly performing a process of forming a redistribution layer 115 a desired number of times. The process of forming the redistribution layer 115 may include a process of forming a first insulating layer 111 using a lamination or coating method (for example, spin coating), a process of forming a via hole in the first insulating layer 111, and a process of forming a first redistribution pattern 112 and a redistribution via 113 using a plating process. For example, the first insulating layer 111 may include a photosensitive insulating material (PID), as described above according to one or more example embodiments. In this case, the via hole may be formed to have an even finer pitch using a photolithography method. In addition, a passivation layer 117 may be formed on the redistribution substrate 110, an opening may be formed in the passivation layer 117, and then an UBM layer 118, connected to the redistribution layer 115, may be formed.

Referring to FIG. 6D, the carrier layer 320 may be removed from the encapsulation layer 150.

In the present example process, the second copper foil 326b may remain on a surface of the encapsulation layer 150 from which the carrier layer 320 is removed. The copper foil 326b, remaining on the encapsulation layer 150, may be used as a plating seed layer to form a heat dissipation pad and a connection pad in a subsequent process (see FIG. 7A).

FIGS. 7A, 7B, 7C, 7D and 7E are cross-sectional views of other processes of a method of manufacturing a semiconductor package according to one or more example embodiments. The example present processes represent a process of manufacturing an upper structure as another part of a process of manufacturing the semiconductor package 100 illustrated in FIG. 1.

Referring to FIG. 7A, heat dissipation pads 170 may be formed on a first portion of an encapsulation layer 150, and connection pads 160 may be formed on a second portion of the encapsulation layer 150.

First, a first hole VH1, passing through the first portion of the encapsulation layer 150 and opening a portion of a heat dissipation layer 130, may be formed, and a second hole VH2, passing through the second portion of the encapsulation layer 150 and opening a portion of a third interconnection layer 142c, may be formed. The first and second holes VH1 and VH2 may be formed together using a laser process.

Subsequently, a photoresist pattern may be formed to open pad formation regions having the first and second holes VH1 and VH2, and the heat dissipation pads 170 and the connection pads 160 may be formed using a plating process. The heat dissipation pads 170 may have a heat dissipation via 175 connected to the heat dissipation layer 130 in the first hole VH1, and the connection pads 160 may have a connection via 165 connected to an interconnection structure 145 (in particular, the third interconnection layer 142c) in the second hole VH2.

The heat dissipation pads 170 and the connection pads 160 may be formed using the same plating process. Thus, the heat dissipation pads 170 may have a structure integrated with the heat dissipation via 175. Similarly, the connection pads 160 may have a structure integrated with the connection via 165. In addition, the heat dissipation pads 170 may include a material the same as that of the connection pads 160. For example, the heat dissipation pads 170 and the connection pads 160 may include copper (Cu). On the encapsulation layer 150, a thickness of each of the heat dissipation pads 170 may be substantially the same as a thickness of each of the connection pads 160. After the plating process is completed, the photoresist pattern may be removed, and an exposed portion of a seed layer (that is, the remaining second copper foil 326b) may be removed.

Referring to FIG. 7B, a mark may be provided by engraving the mark pad 170M using a laser beam L.

The mark pad 170M may be a heat dissipation pad having a relatively large area, among the heat dissipation pads 170. The mark M on the mark pad 170M may be formed as an engraved pattern CV by performing engraving using a laser. A depth at which engraving is performed to engrave the mark M may be less than a thickness of the mark pad 170M. The mark M formed in the present example process may include letters, numbers, recognition codes, and the like, representing various pieces of product information, as illustrated in FIG. 3B.

Referring to FIG. 7C, a bonding metal layer 167 may be formed on the connection pads 160.

In the present process, bonding regions of the connection pads 160 may be opened using a dry film PR, and the bonding metal layer 167 may be formed in a bonding region. For example, the bonding metal layer 167 may include an HASL layer or a Ni/Au plating layer.

Referring to FIG. 7D, an electrical connection metal 119 may be formed on a UBM layer 118. The present example process may be performed after a protective layer 350 is formed to protect the connection pads 160 on which the bonding metal layer 167 is formed, and the heat dissipation pads 170. In one or more example embodiments, a passive component 210 may be mounted on a lower surface of the redistribution substrate 110 and connected to the redistribution layer 115 through the UBM layer 118.

Referring to FIG. 7E, after the protective layer 350 is removed, a heat sink 185 may be formed on the heat dissipation pads 170, and a second semiconductor chip 190 may be formed on the connection pads 160.

In the present example process, the heat sink 185 may be coupled to the heat dissipation pads 170 using a thermally conductive bonding layer 182. The thermally conductive bonding layer 182 may be filled in a space between the heat dissipation pads 170 to ensure high bonding strength. As described above according to one or more example embodiments, a portion of the thermally conductive bonding layer 182 filled in the space between the heat dissipation pads 170 may be bonded to the encapsulation layer 150. For example, the thermally conductive bonding layer 182 may include a TIM.

Second chip pads 195 of the second semiconductor chip 190 may be connected to the connection pads 160 by a conductive bump SB. In one or more example embodiments, the bonding metal layer 167 may be disposed on the connection pads 160. In addition, an underfill may be formed between the second semiconductor chip 190 and the encapsulation layer 150 to surround the conductive bump SB.

According to the above-described one or more example embodiments, heat may be effectively discharged to the outside using a new heat dissipation path including a heat dissipation pad passing through an encapsulation layer covering a first semiconductor chip, the heat dissipation pad being connected to the first semiconductor chip. In addition, at least one of heat dissipation pads may be provided as a mark pad having high visibility.

While example embodiments have been shown and described above, it will be apparent to those skilled in the art that modifications and variations could be made without departing from the spirit and scope of the present disclosure as defined by the following claims.

What is claimed is:

1. A semiconductor package comprising:
a redistribution substrate comprising a redistribution layer;
a frame on the redistribution substrate and defining a cavity, wherein the frame comprises an interconnection structure connected to the redistribution layer and extending to an upper surface of the frame;
a first semiconductor chip on the redistribution substrate and in the cavity, the first semiconductor chip being connected to the redistribution layer, wherein the first semiconductor chip comprises a heat dissipation layer on an upper surface of the first semiconductor chip;
an encapsulation layer comprising:
a first portion on the first semiconductor chip in the cavity; and
a second portion on the upper surface of the frame;
heat dissipation pads on the first portion of the encapsulation layer, each of the heat dissipation pads comprising a heat dissipation via passing through the encapsulation layer, the heat dissipation via being connected to the heat dissipation layer, wherein the heat dissipation pads comprise a mark pad comprising an engraved mark;
connection pads on the second portion of the encapsulation layer, each of the connection pads comprising a connection via passing through the encapsulation layer, the connection via being connected to the interconnection structure;
a second semiconductor chip on the encapsulation layer and connected to the connection pads; and
a heat sink on the heat dissipation pads.

2. The semiconductor package of claim 1, wherein the mark pad has an area that is larger than an area of each of other heat dissipation pads.

3. The semiconductor package of claim 1, further comprising:
a thermally conductive bonding layer between the heat sink and the heat dissipation pads,
wherein the thermally conductive bonding layer thermally couples the heat sink to the heat dissipation pads.

4. The semiconductor package of claim 3, wherein the thermally conductive bonding layer is in a space between the heat dissipation pads and is bonded to the encapsulation layer.

5. The semiconductor package of claim 3, wherein the thermally conductive bonding layer is in the engraved mark of the mark pad.

6. The semiconductor package of claim 1, wherein the engraved mark has a depth that is less than a thickness of the mark pad.

7. The semiconductor package of claim 1, wherein the heat dissipation pads and the connection pads comprise a same material.

8. The semiconductor package of claim 1, wherein a thickness of the heat dissipation pads equals a thickness of the connection pads.

9. The semiconductor package of claim 1, further comprising:
a bonding metal layer on each of the connection pads.

10. The semiconductor package of claim 1, wherein the heat dissipation layer comprises a metal layer, and
wherein an area of the heat dissipation layer corresponds to an area of the upper surface of the first semiconductor chip.

11. The semiconductor package of claim 1, wherein the cavity is adjacent to one side of the frame.

12. The semiconductor package of claim 1, wherein the redistribution layer comprises:
a plurality of redistribution layers; and
a plurality of redistribution vias connected to the plurality of redistribution layers, and
wherein each of the plurality of redistribution vias has a width decreasing toward an upper surface of the redistribution substrate.

13. The semiconductor package of claim 1, further comprising:
a passive component on a lower surface of the redistribution substrate.

14. A semiconductor package comprising:
a redistribution substrate comprising a redistribution layer;
a frame on the redistribution substrate and defining a cavity, wherein the frame comprises an interconnection structure connected to the redistribution layer and to an upper surface of the frame;
a first semiconductor chip on the redistribution substrate and in the cavity, the first semiconductor chip comprising first chip pads connected to the redistribution layer, wherein the first semiconductor chip comprises a heat dissipation layer on an upper surface of the first semiconductor chip;
an encapsulation layer on the upper surface of the frame and filling the cavity, the encapsulation layer having a plurality of openings, which open pad regions of the interconnection structure;
heat dissipation pads on the encapsulation layer, each of the heat dissipation pads comprising a heat dissipation via passing through the encapsulation layer, the heat dissipation via being connected to the heat dissipation layer, wherein the heat dissipation pads comprise a mark pad comprising an engraved mark;
a second semiconductor chip comprising second chip pads connected to the pad regions by conductive bumps; and
a heat sink on the heat dissipation pads.

15. The semiconductor package of claim 14, further comprising:
a thermally conductive bonding layer between the heat sink and the heat dissipation pads,
wherein the thermally conductive bonding layer fills in a space between the heat dissipation pads.

16. The semiconductor package of claim 14, wherein an upper surface of the heat dissipation layer is on a same level as, or lower than, a level of the upper surface of the frame.

17. The semiconductor package of claim 14, further comprising:
a bonding metal layer on each of the pad regions.

18. The semiconductor package of claim 17, wherein upper surfaces of the heat dissipation pads are on a level higher than a level of an upper surface of the bonding metal layer.

19. A semiconductor package comprising:
a redistribution substrate comprising a redistribution layer;
a frame on the redistribution substrate and defining a cavity, wherein the frame comprises an interconnection structure connected to the redistribution layer and extending to an upper surface of the frame;
a first semiconductor chip on the redistribution substrate and in the cavity, the first semiconductor chip comprising first chip pads connected to the redistribution layer, wherein the first semiconductor chip comprises a heat dissipation layer on an upper surface of the first semiconductor chip;
an encapsulation layer comprising:
a first portion encapsulating the first semiconductor chip in the cavity; and
a second portion on the upper surface of the frame;
heat dissipation pads on the first portion of the encapsulation layer, each of the heat dissipation pads comprising a heat dissipation via passing through the encapsulation layer, the heat dissipation via being connected to the heat dissipation layer;
connection pads on the second portion of the encapsulation layer, each of the connection pads comprising a connection via passing through the encapsulation layer, the connection via being connected to the interconnection structure;
a second semiconductor chip on the encapsulation layer, the second semiconductor chip comprising second chip pads respectively connected to the connection pads by a conductive bump;
a heat sink on the heat dissipation pads; and
a thermally conductive bonding layer between the heat sink and the heat dissipation pads, wherein the thermally conductive bonding layer thermally couples the heat sink to the heat dissipation pads.

20. The semiconductor package of claim 19, wherein the heat dissipation pads and the connection pads comprise a same material, and
wherein a thickness of the heat dissipation pads is equal to a thickness of each of the connection pads.
